(19) United States
(12) Patent Application Publication
(10) Pub. No.: US 2013/0043882 A1
(43) Pub. Date: Feb. 21, 2013

(54) APPARATUS AND METHOD FOR TESTING ELECTRONIC EQUIPMENT

(71) Applicant: Glenn D. Albert, Longmont, CO (US)

(72) Inventor: Glenn D. Albert, Longmont, CO (US)

(73) Assignee: TELEPLAN INTERNATIONAL NV, Schiphol (NL)

(21) Appl. No.: 13/213,479

(22) Filed: Aug. 19, 2011

(51) Int. Cl. G01R 1/00

(52) U.S. Cl. 324/555

(57) ABSTRACT

A thermal wrap for testing electronic components has a web having an inside and an outside surface and a first end and a second end and a thermal element incorporated in said web. An edge element incorporated substantially along at least one edge of said web promotes a thermal seal between said web and the electronic component being tested when the electronic component in installed in the wrap. A closure disposed on the ends may be reversibly closed sufficiently tightly to promote the thermal seal.

### BACKGROUND OF THE INVENTION

1. Field of the Invention

The field of the invention is in testing electronic equipment.

2. Related Art

Elevated temperature is a known accelerator in the failure of electronic products and components. Heat is a common problem in the field application of Set Top boxes (“STBs”) wherein the end user often encloses the device in an entertainment center having little or no ventilation or air movement. Certain types of faults occur at elevated temperature but not at room temperature. Certain types of faults occurring at elevated temperature are precursors to eventual failure at lower temperatures. In the after-market repair industry the goal is to find and repair the root cause of all possible forms of malfunction in faulty products returned by customers. Testing at elevated temperature is a means of improving the overall rate of fault detection over testing exclusively at room temperature. The same is true for testing the quality of newly manufactured products. In current practice heat rooms are deployed to enable testing at higher temperature, but the quantity and quality of tests that can be done in a heat room is limited by the effects of higher temperature on operators and test equipment. In addition, heat rooms require significant capital and operating expense.

### SUMMARY OF THE INVENTION

A thermal wrap for testing electronic components has a web having an inside and an outside surface and a first end and a second end and, optionally, a thermal element incorporated in said web. An edge element incorporated substantially along at least one edge of said web promotes a thermal seal between said web and the electronic component being tested when the electronic component in installed in the wrap. A closure disposed on the ends may be reversibly closed sufficiently tightly to promote the thermal seal.

When fastened around a powered electronic device to be tested for faults, a STB in this embodiment, the invention produces higher than normal temperatures within the device, in two ways. First, the thermal treatment, made of fabric and/or other materials, blocks the ventilation holes in the walls of the device, defeating their intended purpose and preventing the heat generated by the powered internal electrical components from escaping the box by free flow of air. Secondly, the insulating effect of the treatment influences the rate of increase of the temperatures inside the device, as well as the ultimate level of steady state temperature reached.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

FIG. 1 is perspective view of an embodiment of the current invention deployed on a set top box.

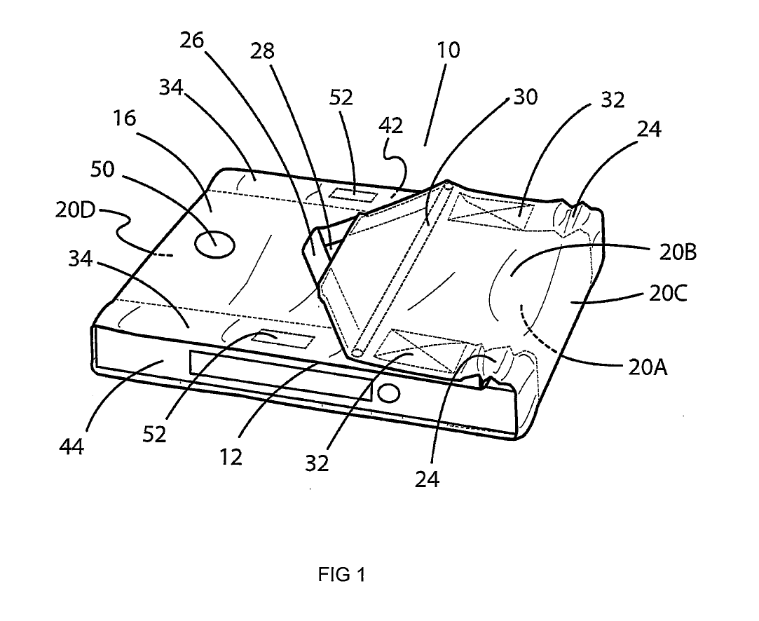

FIG. 2 is perspective view of an embodiment of the current invention when not in use.

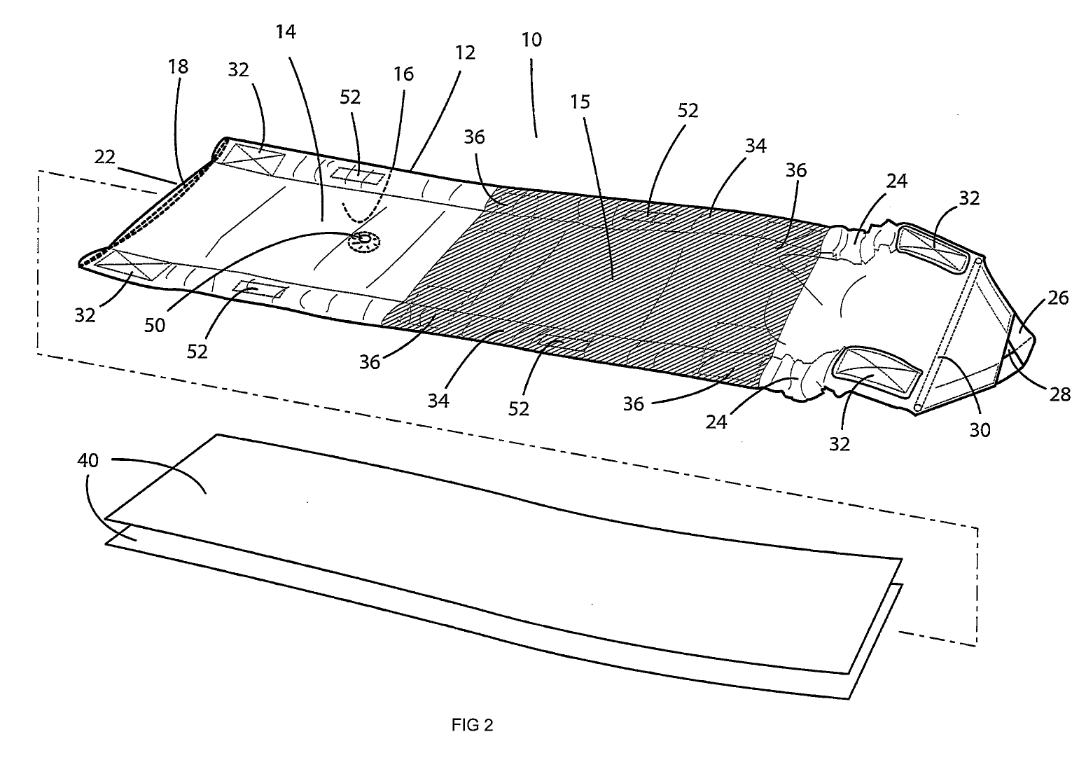

FIG. 3 is perspective view of an embodiment of the current invention partially installed on a set top box at a first installation stage.

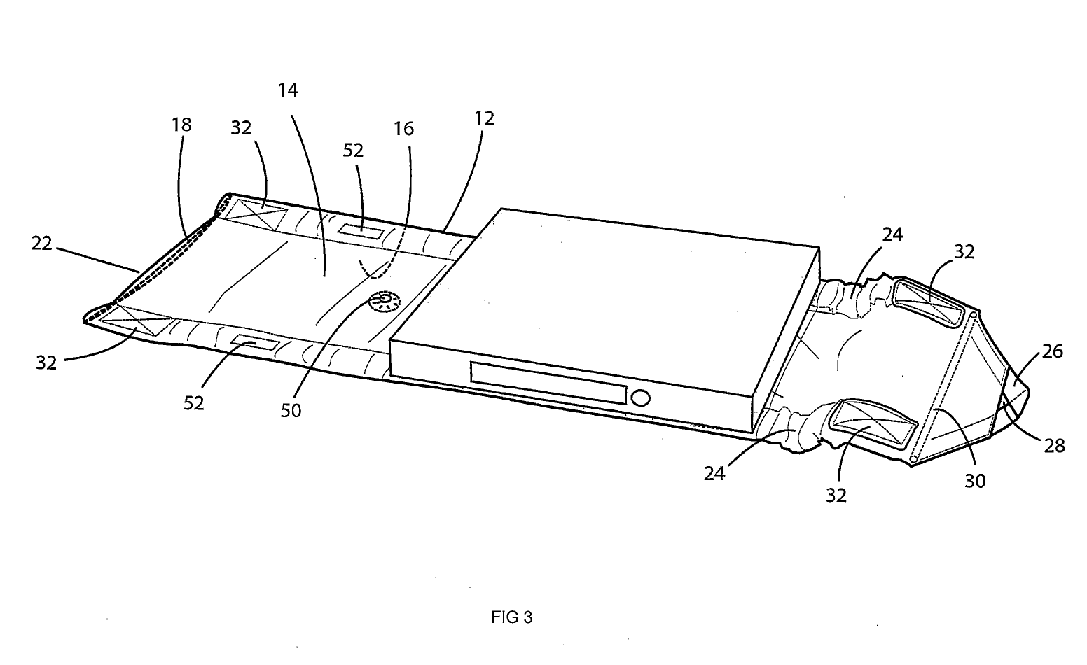

FIG. 4 is perspective view of an embodiment of the current invention partially installed on a set top box at a second installation stage.

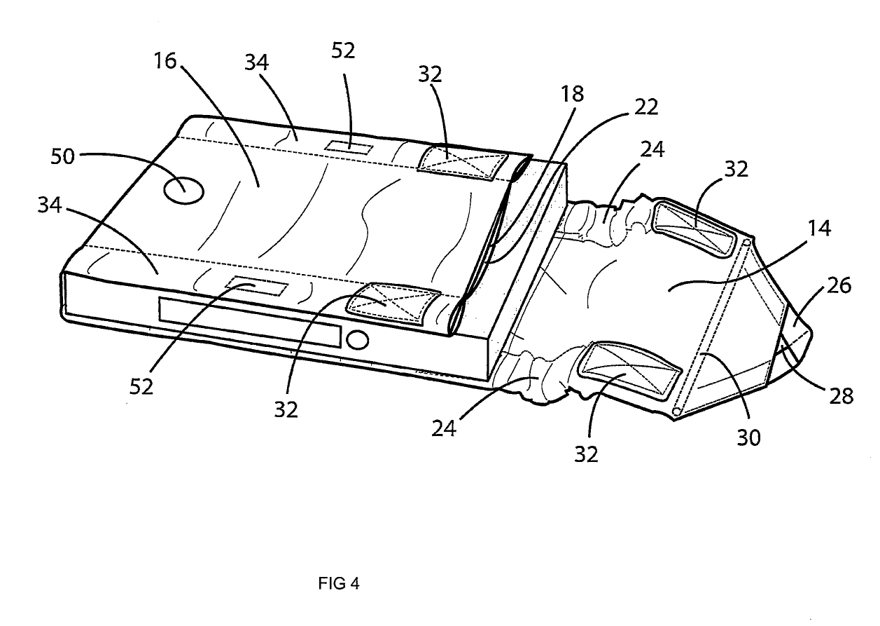

FIG. 5 is perspective view of an embodiment of the current invention deployed on a set top box that is in a test fixture.

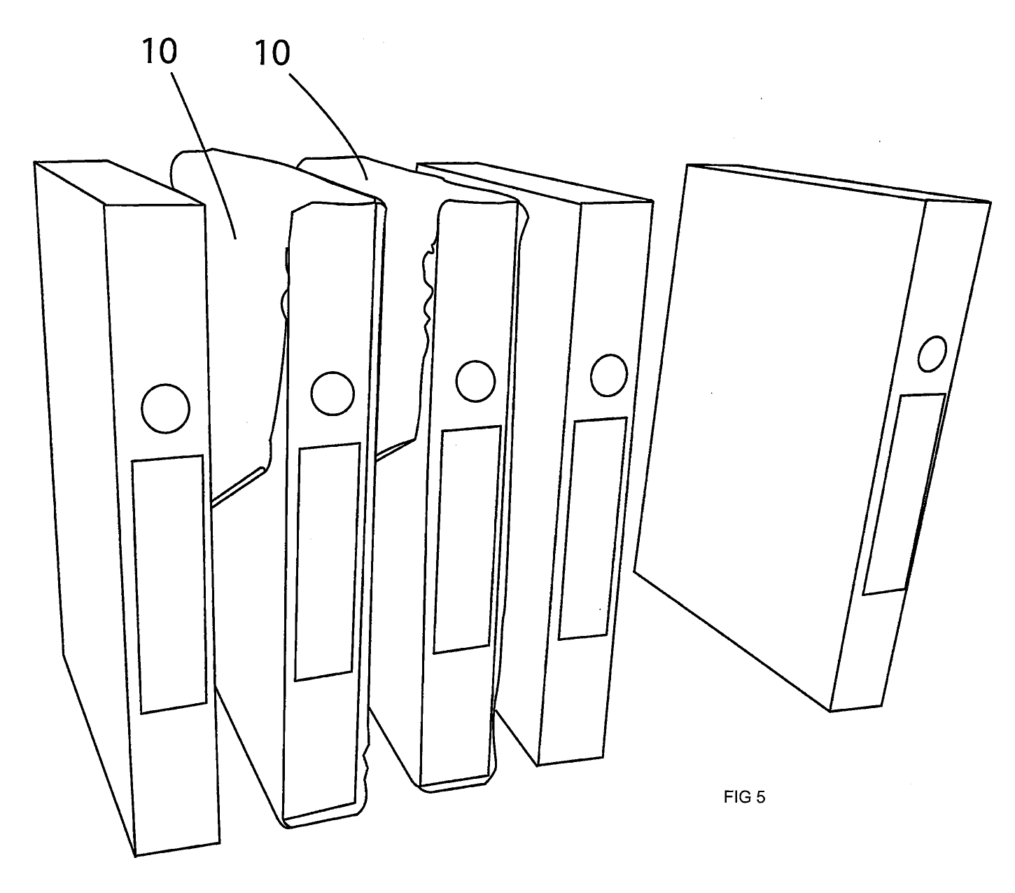

FIG. 6 is perspective view of an embodiment of the current invention.

### DETAILED DESCRIPTION OF THE PREFERRED EMBODIMENTS

Referring to the drawings in which like reference numbers refer to like elements, thermal test wrap 10 is comprised of a web 12 having an inside 14 and an outside 16 surface. In the depicted embodiment, the web 12 has a thermally insulating element 18, which may include insulating material held between a fabric or film comprising the inside and outside surfaces, or may also or alternatively include a reflective material.

Web 12 has sections. In the depicted embodiment, there are four sections 20A, 20B, 20C and 20D corresponding to four of the six sides that set top boxes are typically configured to have. This embodiment covers four of six walls, while intentionally leaving the front and back of the box open as is necessary for test access to buttons and the infrared receiver input on the front panel, and the attachment of power and signal input and output cables on the backside.

All or part of the inside surface 14 may have a different color than the rest to facilitate proper orientation of the wrap in application to a STB. A colored portion 15 of the inside surface 14 may serve as an orientation panel and show the operator a preferred placement of a STB to be tested.

The web 12 may include one or more pockets or slots 22. These allow for the addition or change of inserted panels 40 of additionally insulating material to accommodate a variety of boxes having different thermal behaviors due to a number of factors such as the presence or absence of an integrated cooling fan, the location of the fan, the makeup of internal components that generate heat (power supply, HDD, motherboard, other), the physical size of the box, the ventilation design, amount and location. The one or more inserted panels 40 and the corresponding receiving slots 22 can be substantially the full length of the wrap 10, or sized to cover specific shorter sections.

An elastic section 24 keeps the material stretched tightly all the way around, in the direction of wrapping, at all times as is necessary to maintain the sealing between the treatment and the box at the exposed edges. The elastic element may be integrated and concealed in the lay-up of the fabric layers to prevent it from snagging or being damaged in the production environment. The depicted embodiment has elastic along its edges to create a degree of purse type closure over the edges of the STB under test, further promoting insulation while retaining access. The wrap my be dimensioned to extend slightly beyond the edges of the STB to facilitate a purse type seal defining openings 42 and 44 that may be smaller than the width and height of the front and/or back of the STB being tested.

A handle or hook 26 on the outer terminating end enables the operator to quickly fasten it with one hand while holding the originating end and the box securely down on the table with the other hand. The handle is also designed with a through hole 28 in it to facilitate hanging the wrap on a hook, when not in use, providing for an organized workspace—which is advantageous in a volume production environment. Alternatively, the handle 26 may be sufficiently strong to hang the STB under test should the tester choose to test that way.

A stiff element or batten 30 (a fiberglass rod in the depicted embodiment) may span the width of the wrap and be integrated with the handle in such a way that the material at the terminating end remains at the full width as the operator stretches the outer terminating end into its fastened position.

Mating hook-and-loop fasteners 32, for example, up-facing on the originating end and down-facing on the terminating end of the wrap are positioned such that they are aligned when the operator pulls the terminating end taught over the originating end. Such fasteners may also have sufficient length so as to effectively fasten to each other for a reasonably broad range of box sizes. The elastic, length of the web, and length of fasteners are dimensioned to be used on a wide variety of different sized STBs. Other fasteners may be used without departing from the scope of the invention.

Sealing bands 34 along the full length of both outer edges of the treatment wrap keep the edges in contact with the extreme surfaces of the box, preventing air flow leakage paths at the interfaces. The sealing features may be enhanced by the inclusion of spongy material as a compressable element along the outer edges. The spongy material is internal to the wrap to keep it from snagging or flaking in use. The sealing bands 34 may be coextensive or alternating with elastic portions 24, or they may be aligned in parallel. Either the insertion panels 40 or sealing bands 34 may include magnetic elements to further promote sealing.

The outer shell 16 of the web may be made of a nylon fabric that is durable and moisture and soil resistant in the factory. Rubberized external surfaces 36 beneath the feet of the box prevent unwanted sliding in the test shelf.

A thermometer 50 may be included.

Advantageous adhesion of the web to the STB being tested may be further enhanced with magnets 52, such as at either or both of the insert areas or the edges.

For installation, the wrap is placed on a work bench with the inside surface 14 facing up. The STB is placed on it and the sections 20 are wrapped around the STB, thereby forming a bottom 20A, top 20B and two sides, 20C and 20D. The wrap is fitted to size by applying tension in application, stretching the elastic portions and fixing the fasteners 32 for closure. Optional inserts 40 may be selectively placed in the pockets 22 provided for them according to a user's preference for localizing insulation over a particular component, for example a hard drive, in a particular STB. Connections are then made to power and test equipment through the window 42 created in the back of the wrap upon installation. The wrapped STB is then placed in a burn-in rack or automated tester for testing with controls and displays accessible through a front window 44 defined by the installed wrap. After testing the process is reversed.

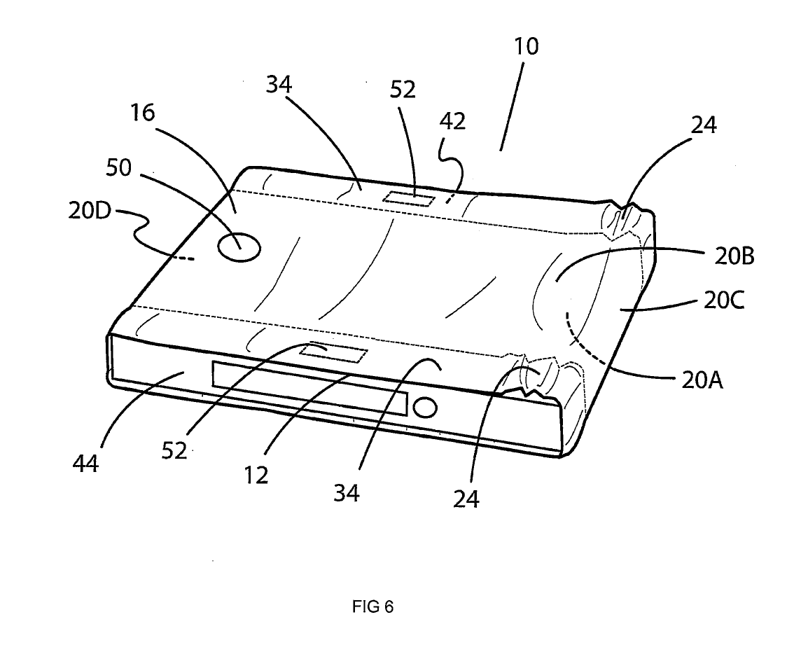

FIG. 6 depicts an alternate embodiment of the current invention configured as a continuous web comprising a sleeve without a closure, such that it may be installed by stretching the edge over the STB and sliding it in place.

In operation the web blocks ventilation holes in the STB housing, decreasing ventilation and increasing heat. Hence, a single layer web is within the scope of the present invention. Increased insulation may optionally be further promoted with, a two layer web, a thermal material such as a reflecting material, an insulating layer, and/or slots for more rigid panels. Edges promoting sealing may be used. It is within the scope of the present invention to test electrical devices other than set top boxes.

As various modifications could be made to the exemplary embodiments, as described above with reference to the corresponding illustrations, without departing from the scope of the invention, it is intended that all matter contained in the foregoing description and shown in the accompanying drawings shall be interpreted as illustrative rather than limiting. Thus, the breadth and scope of the present invention should not be limited by any of the above-described exemplary embodiments, but should be defined only in accordance with the following claims appended hereto and their equivalents.

What is claimed is:

1. A method of testing electronic components comprising:
providing a flexible web;
wrapping said flexible web around an electronic component for testing such that vents in said electronic component are covered;
fixing said flexible web in a substantially thermally sealing relation to an outer surface of the electronic component.

2. The method of claim 1 further comprising using orientation panels on said web.

3. The method of claim 1 further comprising providing at least one slot in said web for receiving an insert.

4. The method of claim 1 wherein said slots are positionable in registry with ventilation holes in an electronic component to be tested.

5. The method of claim 1 further comprising incorporating a batten in said web.

6. The method of claim 1 further comprising said edge element comprising a purse closure.

7. The method of claim 1 wherein said edge includes an elastic element.

8. The method of claim 1 further comprising providing a magnetic element in one of said edge element or an insert for positioning in a slot in said web.

9. The method of claim 1 further comprising attaching a hook on said web.

10. The method of claim 1 wherein said electronic component is a set top box.

11. A thermal wrap for testing electronic components comprising:
a web having an inside surface and an outside surface and an edge;
an edge element incorporated substantially along at least a portion of said edge of said web such that upon installation of said web on an electronic component, said edge element promotes a thermal seal between said web and the electronic component.

12. The thermal wrap of claim 11 further comprising a closure disposed on at a least a portion of said edge such that said web may be reversibly closed sufficiently tightly to promote said thermal seal.

13. The thermal wrap of claim 11 further comprising orientation panels on said web.

14. The thermal wrap of claim 11 further including at least one slot in said web for receiving an insert.

15. The thermal wrap of claim 14 wherein said slots are positionable in registry with ventilation holes in an electronic component to be tested.

16. The thermal wrap of claim 11 further including a batten incorporated in said web.

17. The thermal wrap of claim 11 further comprising said edge element comprising a purse closure.

18. The thermal wrap of claim 11 wherein said edge includes an elastic element.

19. The thermal wrap of claim 11 wherein at least one of said edge element or an insert for positioning in a slot in said web has a magnetic element.

20. The thermal wrap of claim 11 further comprising a hook on said web.

21. The thermal wrap of claim 11 further comprising said wrap having a thermal layer disposed in cooperation with at least part of an area of said web.

22. A thermal wrap for testing electronic components comprising:
a web comprising a first layer, having an inside surface and an outside surface and an edge;
a second layer disposed in cooperation with at least part of an area of said web;
a fixation element on said web disposed such that upon installation of said web on an electronic component, said web promotes a thermal seal between said web and the electronic component.

23. The thermal wrap of claim 22 wherein said fixation element is a closure.

24. The thermal wrap of claim 22 wherein said fixation element is a sealable edge.

25. The thermal wrap of claim 22 wherein said second layer is a thermally insulating layer.

26. The thermal wrap of claim 22 wherein said second layer is attached to said first layer to form a pocket.

27. The thermal wrap of claim 22 wherein said fixation element is further comprised of a closure portioned to releasably close said web such that said inside surface of said web in is a substantially sealing relationship with the electronic component when closed and an edge element incorporated substantially along at least a portion of said edge of said web such that upon installation of said web on an electronic component, said edge element promotes a thermal seal between said edge of said web and the electronic component.

28. The thermal wrap of claim 22 further comprising non-skid pads on said outer surface of said web.

29. The thermal wrap of claim 22 further comprising a thermometer disposed to sense a temperature within said wrap.
